(19) United States
(12) Patent Application Publication
(10) Pub. No.: US 2024/0113505 A1
(43) Pub. Date: Apr. 4, 2024

(54) DRIVE CIRCUIT, CONTROL METHOD FOR DRIVE CIRCUIT AND RECORDING MEDIUM FOR CONTROL PROGRAM

(71) Applicant: NEC Corporation, Tokyo (JP)

(72) Inventor: Mamoru Oguro, Tokyo (JP)

(73) Assignee: NEC Corporation, Tokyo (JP)

(21) Appl. No.: 18/200,294

(22) Filed: May 22, 2023

(30) Foreign Application Priority Data
Sep. 29, 2022 (JP) 2022-156569

(51) Int. Cl. H01S 5/068; H01S 5/042; H01S 5/062

(52) U.S. Cl. CPC H01S 5/06808; H01S 5/042; H01S 5/062

(57) ABSTRACT

In order to achieve a drive circuit being capable of suppressing, with a simple configuration, fluctuation in optical output due to temperature, a drive circuit includes a first terminal and a second terminal being capable of connecting a semiconductor laser diode, a current monitor unit that generates first voltage monotonically decreasing relative to an increase in drive current flowing through the semiconductor laser diode connected between the first terminal and the second terminal, a reference voltage generation unit that generates second voltage monotonically decreasing relative to a rise in ambient temperature, and a control unit that controls the drive current in such a way as to reduce a difference between the first voltage and the second voltage.

This application is based upon and claims the benefit of priority from Japanese Patent Application No. 2022-156569, filed on Sep. 29, 2022, the disclosure of which is incorporated herein in its entirety by reference.

### TECHNICAL FIELD

The present disclosure relates to a drive circuit and the like.

### BACKGROUND ART

Capacity enlargement in an optical transmission system is underway due to an increase in data traffic. In order to deal with a large-capacity optical transmission method, a higher function and a lower cost of a land station and a submarine repeater are required in a land optical transmission system and an optical submarine transmission system. For example, a drive circuit that drives a semiconductor laser diode is used for a light source of an optical signal and an excitation light source of an optical fiber amplifier. Then, the drive circuit is requested to achieve, with a simple configuration, a function of stabilizing optical output. Hereinafter, the semiconductor laser diode is briefly referred to as an “LD”.

FIG. 7 is an exemplary diagram illustrating a general circuit of a drive circuit 900 that drives an LD. The drive circuit 900 includes resistors R1, R4, and R5, an LD 910, and a control circuit 920. Voltage V1 indicates voltage of power supply voltage Vcc after a voltage drop by the resistor R1. Drive current of the LD 910 can be controlled at a constant value by keeping the voltage V1 constant. Voltage V2 is constant voltage into which the power supply voltage Vcc is divided by the resistors R4 and R5, and is constant regardless of temperature. The control circuit 920 controls drive current of the LD 910 in such a way that the voltage V1 approximates the voltage V2. Since the voltage V2 is constant, the control circuit 920 can drive the LD 910 with constant current, by setting the voltage V2 in such a way that current flowing through the LD 910 becomes a desired value.

In relation to the present disclosure, Patent Literature (PTL) 1 describes a constant-current drive circuit of an LD.
[PTL 1] Japanese Unexamined Patent Application Publication No. H08-274395

### SUMMARY

Threshold current of a general LD increases at high temperature, and slope efficiency (SE) decreases at high temperature. Herein, the threshold current is current with which an LD starts laser oscillation. The slope efficiency is a change amount of light output relative to a change amount of drive current of the LD, and has a unit of W/A. The slope efficiency is also represented as inclination of a current-optical output characteristic of the LD. Due to such a characteristic of the LD, a large fluctuation occurs in optical output of the LD in response to a fluctuation in temperature, when the LD is driven with constant-current. Such a fluctuation in optical output significantly occurs particularly when the LD is driven with current being proximate to threshold current.

FIG. 8 is an exemplary diagram illustrating a relation between drive current and optical output of the LD 910 in FIG. 7. A horizontal axis (Id) indicates the drive current of the LD 910, and a vertical axis (P) indicates the optical output of the LD 910. FIG. 8 illustrates an example of a current-optical output characteristic (hereinafter, referred to as an “I-L characteristic”) in each of cases where ambient temperature of the LD 910 is low temperature and temperature being higher than the low temperature. Herein, the “low temperature” refers to, for example, a normal temperature of about 25° C., and the “high temperature” refers to temperature (e.g., about 40° C.) being higher than the “low temperature”. Id1 is drive current when optical output of the LD 910 is low (i.e., when drive current is proximate to threshold current), and Id2 is drive current when optical output is larger than Id1. FIG. 8 illustrates assuming that optical output P of the LD 910 is 0 when drive current Id of the LD 910 is less than threshold current, and the optical output P increases linearly relative to drive current when the drive current Id of the LD 910 is equal to or more than the threshold current.

When ambient temperature of the LD 910 rises, inclination of an I-L characteristic (i.e., slope efficiency) becomes small. Threshold current Ith2 when ambient temperature of the LD 910 is high is larger than threshold current Ith1 when ambient temperature of the LD 910 is low. Thus, when ambient temperature of the LD 910 changes from low temperature to high temperature, optical output of the LD 910 changes in a downward direction in FIG. 8, even by driving the LD 910 with the same current (Id1 or Id2). In other words, optical output decreases as indicated by a difference between “P1 (low temperature)” and “P1 (high temperature)” or a difference between “P2 (low temperature)” and “P2 (high temperature)”. A decrease rate of the optical output is larger as the drive current Id is smaller.

Fluctuation due to temperature of the optical output of the LD 910 illustrated in FIG. 8 becomes a cause of fluctuation in transmission level of an optical signal or fluctuation in gain of an optical amplifier. In other words, there is a concern that fluctuation in ambient temperature of the LD 910 has a bad influence on transmission quality of an optical transmission system. Therefore, an LD drive circuit to be used in an optical transmission system is required to be capable of suppressing, with a simple configuration, fluctuation in optical output relative to a temperature change.

An exemplary object of the disclosure is to provide a technique for providing a drive circuit being capable of suppressing, with a simple configuration, fluctuation in optical output due to temperature.

A drive circuit according to an exemplary embodiment of the present disclosure includes:
a first terminal and a second terminal being capable of connecting a semiconductor laser diode;
a current monitor means for generating first voltage monotonically decreasing relative to drive current flowing through the semiconductor laser diode connected between the first terminal and the second terminal;
a reference voltage generation means for generating second voltage monotonically decreasing relative to ambient temperature; and
a control means for controlling the drive current in such a way as to reduce a difference between the first voltage and the second voltage.

A control method for a drive circuit according to an exemplary embodiment of the present disclosure includes a procedure of:
generating first voltage monotonically decreasing relative to drive current;
generating second voltage monotonically decreasing relative to ambient temperature; and
controlling the drive current in such a way as to reduce a difference between the first voltage and the second voltage.

A recording medium for control program according to an exemplary embodiment of the present disclosure includes a tangible and non-transitory recording medium for control program for causing a computer included in a control unit of drive current to execute:
a procedure of acquiring first voltage monotonically decreasing relative to drive current;
a procedure of acquiring second voltage monotonically decreasing relative to ambient temperature; and
a procedure of controlling the drive current in such a way as to reduce a difference between the first voltage and the second voltage.

The present disclosure enables providing a drive circuit being capable of suppressing, with a simple configuration, fluctuation in optical output due to temperature.

### BRIEF DESCRIPTION OF THE DRAWINGS

Exemplary features and advantages of the present disclosure will become apparent from the following detailed description when taken with the accompanying drawings in which:

FIG. 1 is an exemplary diagram illustrating a configuration example of a drive circuit according to a first example embodiment;

FIG. 2 is an exemplary diagram illustrating a configuration example of a drive circuit according to a second example embodiment;

FIG. 3 is an exemplary diagram illustrating a configuration example of a diode group;

FIG. 4 is an exemplary diagram illustrating a configuration example of the diode group;

FIG. 5 is an exemplary diagram illustrating an example of a relation between drive current and optical output of an LD, according to the second example embodiment;

FIG. 6 is a flowchart illustrating an example of a control method for a drive circuit;

FIG. 7 is an exemplary diagram illustrating a general circuit of the drive circuit; and

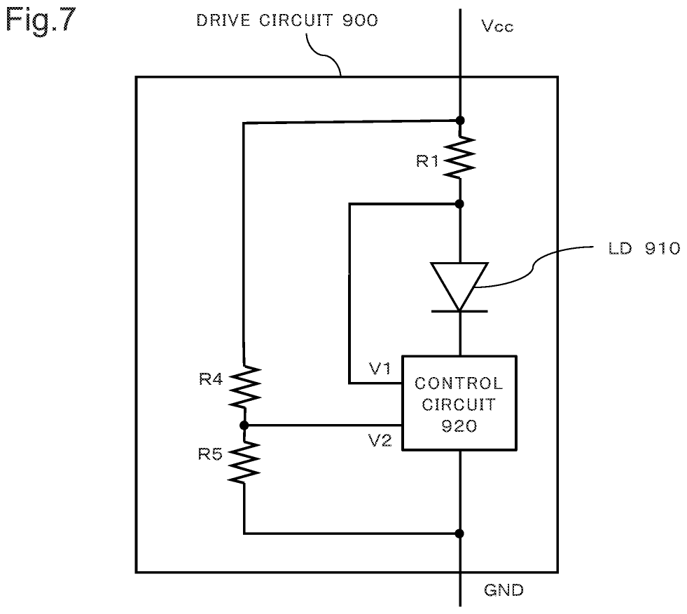

FIG. 8 is an exemplary diagram illustrating a relation between drive current and optical output of an LD.

### EXAMPLE EMBODIMENT

Example embodiments of the present disclosure will be described below with reference to the drawings. In the example embodiments and the drawings, repeated description may be omitted by assigning the same reference sign to a described element.

### First Example Embodiment

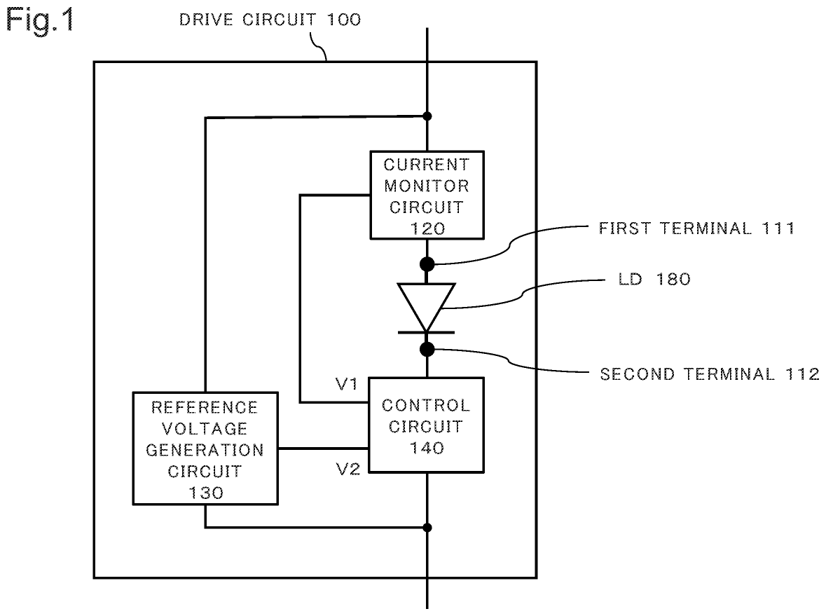

FIG. 1 is an exemplary diagram illustrating a configuration example of a drive circuit 100 according to a first example embodiment of the present disclosure. The drive circuit 100 includes a first terminal 111, a second terminal 112, a current monitor circuit 120, a reference voltage generation circuit 130, and a control circuit 140. The first terminal 111 and the second terminal 112 are electric interfaces being capable of connecting a general semiconductor laser diode (LD) 180 inside or outside the drive circuit 100. Note that the LD 180 may not be included in the drive circuit 100.

The LD 180 is connected between the first terminal 111 and the second terminal 112. The current monitor circuit 120 outputs first voltage V1. The first voltage V1 monotonically decreases relative to an increase in current (drive current) flowing through the LD 180. The first voltage V1 monotonically rises relative to a decline in drive current. The reference voltage generation circuit 130 outputs second voltage V2. The second voltage V2 monotonically decreases relative to a rise in ambient temperature of the drive circuit 100. The second voltage V2 monotonically rises relative to a decrease in ambient temperature of the drive circuit 100. The first voltage V1 and the second voltage V2 are input to the control circuit 140. The control circuit 140 controls drive current in such a way as to reduce a difference between the first voltage V1 and the second voltage V2. Note that, the current monitor circuit 120 is one mode of a current monitor means, and the reference voltage generation circuit 130 is one mode of a reference voltage generation means. The control circuit 140 is one mode of a control means.

The drive circuit 100 including such a configuration is able to suppress, with a simple configuration, fluctuation in optical output of the LD 180 relative to a temperature change. A reason for this is as follows.

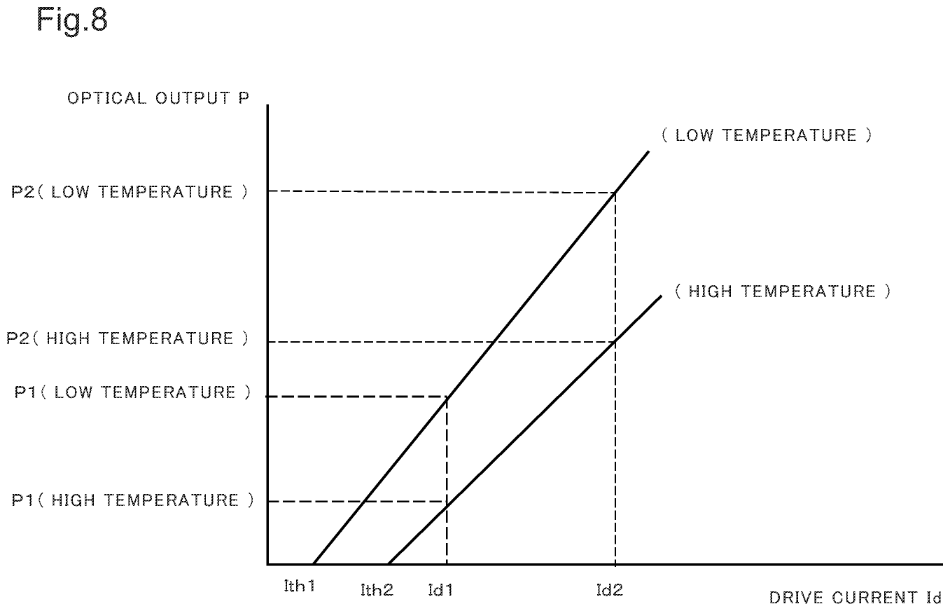

The LD 180 rises in threshold current and decreases in slope efficiency when ambient temperature rises. The ambient temperature is temperature of a space including the LD 180 and the reference voltage generation circuit 130. Thus, when the LD 180 is driven with constant drive current, optical output of the LD 180 decreases due to a rise in ambient temperature, as described with FIG. 8.

However, in the drive circuit 100 according to the present example embodiment, when ambient temperature of the drive circuit 100 rises, the second voltage V2 output by the reference voltage generation circuit 130 decreases. Then, the control circuit 140 controls drive current of the LD 180 in such a way that the first voltage V1 approximates the second voltage V2. Herein, since the first voltage V1 monotonically decreases relative to an increase in drive current, the control circuit 140 increases the drive current in order to decrease the first voltage V1. As a result, optical output of the LD 180 increases, and a decrease in optical output of the LD 180 resulting from a rise in ambient temperature of the drive circuit 100 is suppressed. In this way, the control circuit 140 increases drive current of the LD 180 when temperature rises.

When ambient temperature decreases as well, the drive circuit 100 operates in such a way as to suppress a rise in optical output of the LD 180 resulting from a decrease in ambient temperature. In other words, when ambient temperature decreases, the second voltage V2 output by the reference voltage generation circuit 130 rises. Meanwhile, since the first voltage V1 monotonically rises relative to a decline in drive current, the control circuit 140 decreases drive current in order to raise the first voltage V1. Then, a rise in optical output of the LD 180 resulting from a decrease in ambient temperature is suppressed by the decline in the drive current.

Thus, the drive circuit 100 operates in such a way as to suppress fluctuation in optical output of the LD 180 resulting from a change in ambient temperature. As a result, the drive circuit can stabilize optical output of the LD 180. The LD 180 is used for, for example, a light source of a transmitter used in an optical transmission system or an excitation light source of an optical fiber amplifier.

### Second Example Embodiment

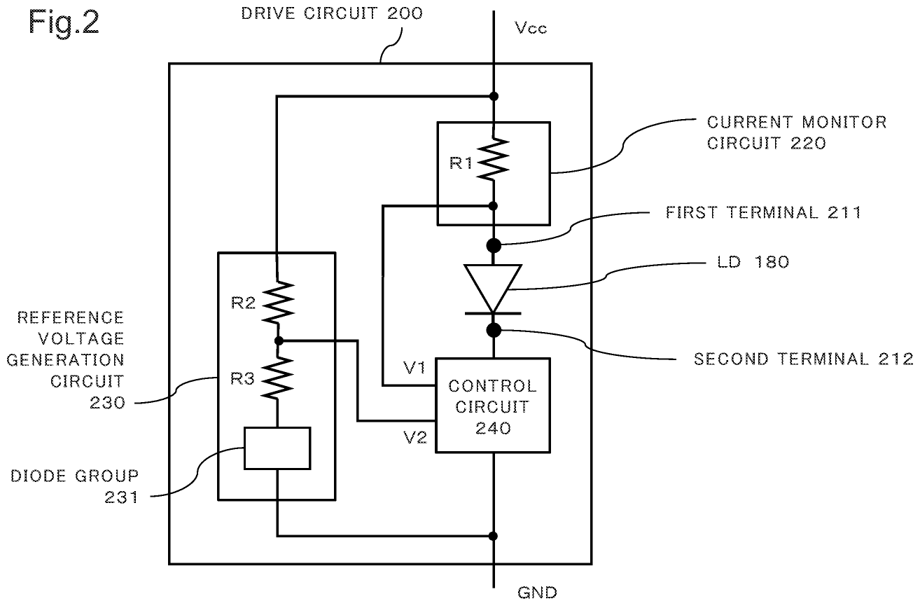

FIG. 2 is an exemplary diagram illustrating a configuration example of a drive circuit 200 according to a second example embodiment of the present disclosure. In the second example embodiment, specific configuration examples of a current monitor circuit 120 and a reference voltage generation circuit 130 described in the first example embodiment are described.

The drive circuit 200 includes a first terminal 211, a second terminal 212, a current monitor circuit 220, a reference voltage generation circuit 230, and a control circuit 240. The first terminal 211 and the second terminal 212 are associated with the first terminal 111 and the second terminal 112 according to the first example embodiment. The current monitor circuit 220, the reference voltage generation circuit 230, and the control circuit 240 are associated with the current monitor circuit 120, the reference voltage generation circuit 130, and the control circuit 140 according to the first example embodiment, respectively.

An anode of an LD 180 is connected to the first terminal 211, and a cathode of the LD 180 is connected to the second terminal 212. The current monitor circuit 220 includes a resistor R1. The resistor R1 is arranged between the first terminal 211 and a positive power supply (Vcc).

The current monitor circuit 220 outputs, as first voltage V1, voltage between the resistor R1 and the first terminal 211. When the LD 180 is connected between the first terminal 211 and the second terminal 212, a voltage drop (Id×R1) of the resistor R1 increases in response to a rise in drive current of the LD 180. Since the first voltage V1 is represented by Vcc−(Id×R1), the first voltage V1 monotonically decreases relative to an increase in drive current of the LD 180.

The reference voltage generation circuit 230 includes resistors R2 and R3, and a diode group 231. One end of the resistor R2 is connected to Vcc, and another end of the resistor R2 is connected to one end of the resistor R3. Another end of the resistor R3 is connected to one end of the diode group 231, and another end of the diode group 231 is grounded (i.e., connected to GND). The resistors R2 and R3, and the diode group 231 are connected in series in this order. Then, the reference voltage generation circuit 230 outputs, as second voltage V2, voltage between the resistors R2 and R3.

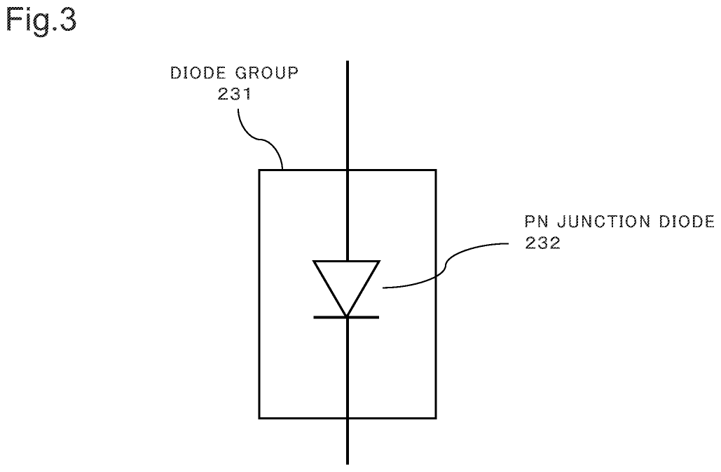

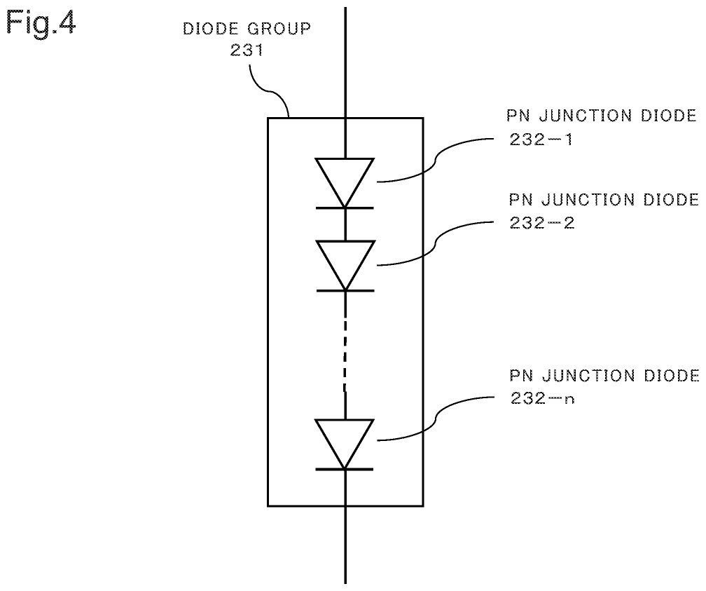

Each of FIGS. 3 and 4 is an exemplary diagram illustrating a configuration example of the diode group 231. The diode group 231 includes one or a plurality of semiconductor diodes. FIG. 3 illustrates an example in which the diode group 231 is constituted of one PN junction diode 232. FIG. 4 illustrates an example in which the diode group 231 is constituted of n PN junction diodes 232-1 to 232-n. n is an integer of equal to or more than 2. The PN junction diodes 232-1 to 232-n are connected in series. In each of cases in FIGS. 3 and 4, the PN junction diode 232 is connected to the power supply Vcc in a forward direction. In other words, each of the PN junction diodes 232 has an anode on the resistor R3 side, and a cathode on the GND side.

A voltage drop of the one PN junction diode 232 in a forward direction is about 0.5 V in a case of a silicon diode, and has a temperature characteristic of about −2 mV/° C. In other words, when ambient temperature of the drive circuit 200 rises, a voltage drop of the PN junction diode 232 declines. Since a voltage drop of the diode group 231 is voltage (i.e., GND-side voltage of the resistor R3) of a connection point between the resistor R3 and the diode group 231 in FIG. 2, the second voltage V2 divided by the resistors R2 and R3 also decreases when a voltage drop of the diode group 231 is reduced. Meanwhile, the control circuit 240 controls drive current of the LD 180 in such a way that the first voltage V1 and the second voltage V2 approximate each other. Thus, when a voltage drop of the diode group 231 is reduced, the control circuit 240 increases drive current of the LD 180 in order to decrease the first voltage V1.

In this way, the control circuit 240 increases drive current of the LD 180 when ambient temperature of the drive circuit 200 rises. By such an operation, the drive circuit 200 is able to suppress fluctuation in optical output resulting from a temperature characteristic of optical output of the LD 180. Note that, a change amount, due to temperature, of the second voltage V2 generated by the reference voltage generation circuit 230 can be adjusted by suitably selecting a number n of the PN junction diodes 232 connected in series in the diode group 231. For example, a temperature characteristic of a voltage drop of the diode group 231 becomes about −6 m V/° C. by connecting the three PN junction diodes 232 in series in the diode group 231. In other words, in this case, sensitivity of the second voltage V2 to a temperature change can be tripled as compared with a case where only the one PN junction diode 232 is used. For a number of series n of the PN junction diodes 232, a number that seems to be preferable may be previously selected according to an individual difference or the like of the LD 180.

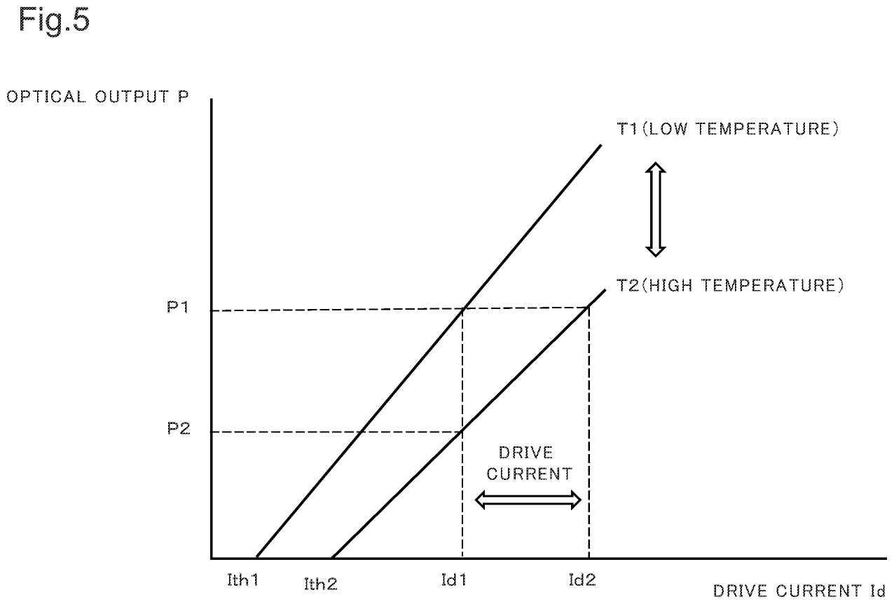

FIG. 5 is an exemplary diagram illustrating an example of a relation between drive current and optical output of the LD 180 when the drive circuit 200 according to the present example embodiment is used. In FIG. 5, it is assumed that a specified value of optical output of the LD 180 is P1. The specified value is, for example, optical output of the LD 180, based on a specification of an optical transmission system in which the LD 180 is used. In FIG. 5, at temperature T1 (low temperature), threshold current of the LD 180 is Ith1, and drive current at which optical output becomes P1 is Id1. Further, at temperature T2 (high temperature), threshold current of the LD 180 is Ith2, and drive current at which optical output becomes P1 is Id2. As in FIG. 8, “low temperature” in FIG. 5 refers to, for example, a normal temperature of about 25° C., and “high temperature” refers to a temperature (e.g., about 40° C.) higher than “low temperature”. Then, when ambient temperature of the LD 180 is high, inclination of an I-L characteristic (i.e., slope efficiency) is small as compared with a case where ambient temperature is low. Note that, FIG. 5 illustrates assuming that optical output of the LD 180 is 0 when drive current of the LD 180 is less than threshold current, and optical output P linearly increases relative to drive current at equal to or more than threshold current.

When ambient temperature changes but drive current of the LD 180 is not controlled, the drive current Id remains at Id1. Thus, when ambient temperature rises from T1 to T2, optical output of the LD 180 decreases from P1 to P2.

However, in the above-described drive circuit 200 in FIG. 2, the control circuit 240 controls drive current according to a change in ambient temperature, and, thereby, a change in drive current relative to a change in ambient temperature is suppressed. In other words, when ambient temperature fluctuates, the drive circuit 200 according to the present example embodiment controls drive current of the LD 180 in such a way as to suppress fluctuation of optical output of the LD 180 attributed to the fluctuation of the ambient temperature. FIG. 5 illustrates an example in which, when ambient temperature of the LD 180 fluctuates between T1 and T2, the control circuit 240 changes drive current between Id1 and Id2, and, thereby, the optical output P is kept at P1 between T1 and T2 of ambient temperature.

However, a control amount of drive current of the LD 180 relative to a change in ambient temperature is influenced by a change rate of the second voltage V2 to a temperature change, and a change rate of drive current to a change of the second voltage V2. Thus, as a change amount of the second voltage V2 relative to a change in ambient temperature, a value that minimizes fluctuation of the optical output P of the LD 180 relative to a change in ambient temperature may be selected. A change amount of the second voltage V2 relative to a change in ambient temperature may be set by selecting, by a preliminary evaluation, a type and the number of series of the PN junction diode 232. For example, first, the drive circuit 200 is operated by use of each of the diode groups 231 having different numbers of series n. Then, the diode group 231 having the number of series with which stability against ambient temperature of optical output of the LD 180 is the highest may be finally mounted on the drive circuit 200.

A temperature characteristic of the second voltage V2 output from the diode group 231 does not necessarily need to have such a characteristic that can keep optical output of the LD 180 strictly constant within ranges of ambient temperature and drive current in which the drive circuit 200 is used. As a specification and the number of series of the PN junction diode 232 used in the diode group 231, different specifications and numbers of series may be selected depending on a specification and an individual difference of the LD 180, and a specification or the like of power of an optical signal required by an optical transmission system.

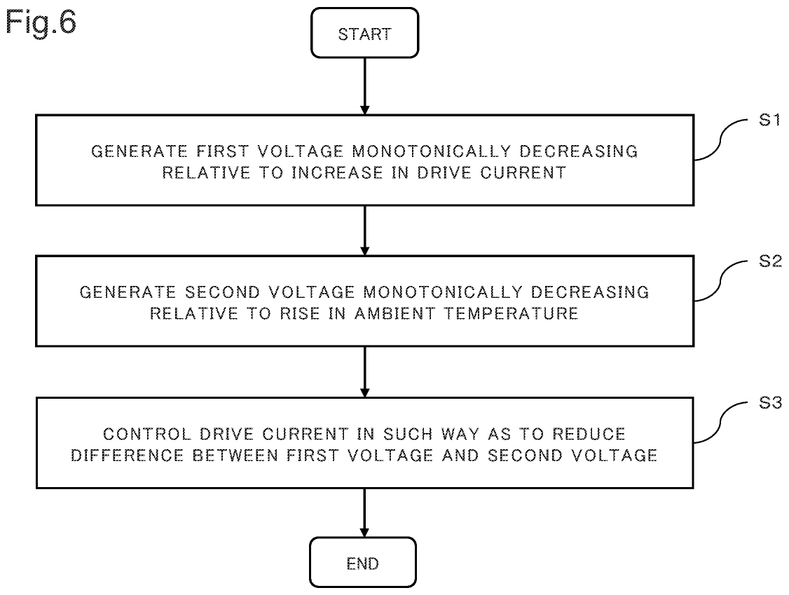

FIG. 6 illustrates, as a flowchart, a control method for a drive circuit in the above-described drive circuit 200. The drive circuit 200 generates first voltage (V1) monotonically decreasing relative to an increase in drive current (step S1 in FIG. 6). The drive circuit 200 generates second voltage (V2) monotonically decreasing relative to a rise in ambient temperature (step S2). Steps S1 and S2 may be in reverse order or may be simultaneous. Then, the control circuit 240 controls drive circuit in such a way as to reduce a difference between the first voltage and the second voltage.

Herein, the first voltage V1 may be generated by dividing power supply voltage (Vcc) by use of a functional element (the diode group 231) in which a temperature characteristic of a voltage drop is a negative value. The functional element is constituted of, for example, one semiconductor diode or a plurality of semiconductor diodes connected in series. Then, the first voltage V1 may be generated by dividing voltage (Vcc) supplied to the drive circuit 200, by use of resistors (R2 and R3) connected in series to the functional element. Then, by a procedure in FIG. 6, the drive circuit 200 increases drive current of the LD 180 when ambient temperature rises. As a result, the drive circuit 200 can suppress fluctuation in optical output resulting from a temperature characteristic of optical output of the LD 180.

While the disclosure has been particularly shown and described with reference to example embodiments thereof, the disclosure is not limited to these embodiments. It will be understood by those of ordinary skill in the art that various changes in form and details may be made therein without departing from the spirit and scope of the present disclosure as defined by the claims.

Some or all of the functions and procedures described in each example embodiment may be achieved by executing a control program by a central processing unit (CPU) included in the drive circuit 100 or the drive circuit 200.

For example, a control program causes a computer included in a control circuit of drive current to execute a procedure of acquiring first voltage monotonically decreasing relative to drive current. The control program causes the computer to execute a procedure of acquiring second voltage monotonically decreasing relative to ambient temperature. Then, the control program causes the computer to execute a procedure of controlling the drive current. Herein, the drive current is controlled in such a way as to reduce a difference between the first voltage and the second voltage.

The control program is recorded in a fixed and non-transitory recording medium. A semiconductor memory is used as the recording medium, but the recording medium is not limited thereto. The computer is, for example, a CPU included in the control circuit 140 or 240.

Note that, the example embodiments of the present disclosure may also be described as, but are not limited to, the following supplementary notes.

(Supplementary Note 1)

A drive circuit including:
a first terminal and a second terminal being capable of connecting a semiconductor laser diode;
a current monitor means for generating first voltage monotonically decreasing relative to an increase in drive current flowing through the semiconductor laser diode connected between the first terminal and the second terminal;
a reference voltage generation means for generating second voltage monotonically decreasing relative to a rise in ambient temperature; and
a control means for controlling the drive current in such a way as to reduce a difference between the first voltage and the second voltage.

(Supplementary Note 2)

The drive circuit according to supplementary note 1, wherein the reference voltage generation means generates the first voltage by dividing power supply voltage by use of a functional element in which a temperature characteristic of a voltage drop is a negative value.

(Supplementary Note 3)

The drive circuit according to supplementary note 2, wherein the functional element is constituted of one semiconductor diode or a plurality of semiconductor diodes connected in series.

(Supplementary Note 4)

The drive circuit according to supplementary note 2 or 3, wherein the first voltage is generated by dividing voltage supplied to the drive circuit, by use of resistors connected in series to the functional element.

(Supplementary Note 5)

The drive circuit according to any one of supplementary notes 1 to 4, wherein, as a change amount of the second voltage relative to a change in the ambient temperature, a value that suppresses fluctuation of optical output of the semiconductor laser diode resulting from a change in the ambient temperature is selected.

(Supplementary Note 6)

A control method for a drive circuit, including:
generating first voltage monotonically decreasing relative to an increase in drive current of a semiconductor laser diode;
generating second voltage monotonically decreasing relative to a rise in ambient temperature; and
controlling the drive current in such a way as to reduce a difference between the first voltage and the second voltage.

(Supplementary Note 7)

The control method for the drive circuit according to supplementary note 6, further including generating the first voltage by dividing power supply voltage by use of a functional element in which a temperature characteristic of a voltage drop is a negative value.

(Supplementary Note 8)

The control method for the drive circuit according to supplementary note 7, further including generating the first voltage by use of the functional element constituted of one semiconductor diode or a plurality of semiconductor diodes connected in series.

(Supplementary Note 9)

The control method for the drive circuit according to supplementary note 7 or 8, further including generating the first voltage by dividing voltage supplied to the drive circuit, by use of resistors connected in series to the functional element.

(Supplementary Note 10)

The control method for the drive circuit according to any one of supplementary notes 6 to 9, further including selecting, as a change amount of the second voltage relative to a change in the ambient temperature, a value that suppresses fluctuation of optical output, of a semiconductor laser diode driven by the drive current, resulting from a change in the ambient temperature.

(Supplementary Note 11)

A control program for causing a computer included in a control circuit of drive current to execute:
a procedure of acquiring first voltage monotonically decreasing relative to drive current;
a procedure of acquiring second voltage monotonically decreasing relative to ambient temperature; and
a procedure of controlling the drive current in such a way as to reduce a difference between the first voltage and the second voltage.

The previous description of embodiments is provided to enable a person skilled in the art to make and use the present disclosure. Moreover, various modifications to these example embodiments will be readily apparent to those skilled in the art, and the generic principles and specific examples defined herein may be applied to other embodiments without the use of inventive faculty. Therefore, the present disclosure is not intended to be limited to the example embodiments described herein but is to be accorded the widest scope as defined by the limitations of the claims and equivalents.

Further, it is noted that the inventor's intent is to retain all equivalents of the claimed disclosure even if the claims are amended during prosecution.

Reference Signs List

| | |
|---|---|
| 100, 200 | Drive circuit |
| 111, 211 | First terminal |
| 112, 212 | Second terminal |
| 120, 220 | Current monitor circuit |
| 130, 230 | Reference voltage generation circuit |
| 140, 240 | Control circuit |
| 180 | Semiconductor laser diode (LD) |
| 231 | Diode group |
| 232, 232-1 to 232-n | PN junction diode |
| 900 | Drive circuit |
| 920 | Control circuit |

1. A drive circuit comprising:
a first terminal and a second terminal being capable of connecting a semiconductor laser diode;
a current monitor unit configured to generate first voltage monotonically decreasing relative to an increase in drive current flowing through the semiconductor laser diode connected between the first terminal and the second terminal;
a reference voltage generation unit configured to generate second voltage monotonically decreasing relative to a rise in ambient temperature; and
a control unit configured to control the drive current in such a way as to reduce a difference between the first voltage and the second voltage.

2. The drive circuit according to claim 1, wherein the reference voltage generation unit generates the first voltage by dividing power supply voltage by use of a functional element in which a temperature characteristic of a voltage drop is a negative value.

3. The drive circuit according to claim 2, wherein the functional element is constituted of one semiconductor diode or a plurality of semiconductor diodes connected in series.

4. The drive circuit according to claim 2, wherein the first voltage is generated by dividing voltage supplied to the drive circuit, by use of resistors connected in series to the functional element.

5. The drive circuit according to claim 3, wherein the first voltage is generated by dividing voltage supplied to the drive circuit, by use of resistors connected in series to the functional element.

6. The drive circuit according to claim 1, wherein, as a change amount of the second voltage relative to a change in the ambient temperature, a value that suppresses fluctuation of optical output of the semiconductor laser diode resulting from a change in the ambient temperature is selected.

7. The drive circuit according to claim 2, wherein, as a change amount of the second voltage relative to a change in the ambient temperature, a value that suppresses fluctuation of optical output of the semiconductor laser diode resulting from a change in the ambient temperature is selected.

8. A control method for a drive circuit, comprising:
generating first voltage monotonically decreasing relative to an increase in drive current of a semiconductor laser diode;
generating second voltage monotonically decreasing relative to a rise in ambient temperature; and
controlling the drive current in such a way as to reduce a difference between the first voltage and the second voltage.

9. The control method for the drive circuit according to claim 8, further comprising generating the first voltage by dividing power supply voltage by use of a functional element in which a temperature characteristic of a voltage drop is a negative value.

10. The control method for the drive circuit according to claim 9, further comprising generating the first voltage by use of the functional element constituted of one semiconductor diode or a plurality of semiconductor diodes connected in series.

11. The control method for the drive circuit according to claim 9, further comprising generating the first voltage by dividing voltage supplied to the drive circuit, by use of resistors connected in series to the functional element.

12. The control method for the drive circuit according to claim 10, further comprising generating the first voltage by dividing voltage supplied to the drive circuit, by use of resistors connected in series to the functional element.

13. The control method for the drive circuit according to claim 8, further comprising selecting, as a change amount of the second voltage relative to a change in the ambient temperature, a value that suppresses fluctuation of optical output, of a semiconductor laser diode driven by the drive current, resulting from a change in the ambient temperature.

14. The control method for the drive circuit according to claim 9, further comprising selecting, as a change amount of the second voltage relative to a change in the ambient temperature, a value that suppresses fluctuation of optical output, of a semiconductor laser diode driven by the drive current, resulting from a change in the ambient temperature.

15. A tangible and non-transitory recording medium for control program for causing a computer included in a control unit of drive current to execute:
a procedure of acquiring first voltage monotonically decreasing relative to drive current;
a procedure of acquiring second voltage monotonically decreasing relative to ambient temperature; and
a procedure of controlling the drive current in such a way as to reduce a difference between the first voltage and the second voltage.
